(19) United States
(12) Patent Application Publication
(10) Pub. No.: US 2014/0021432 A1
(43) Pub. Date: Jan. 23, 2014

(54) VARIABLE RESISTANCE MEMORY DEVICE AND METHOD FOR FABRICATING THE SAME

(71) Applicant: SK HYNIX INC., Gyeonggi-do (KR)

(72) Inventor: Sung-Hoon LEE, Gyeonggi-do (KR)

(73) Assignee: SK HYNIX INC., Gyeonggi-do (KR)

(21) Appl. No.: 13/718,875

(22) Filed: Dec. 18, 2012

(30) Foreign Application Priority Data
Jul. 20, 2012 (KR) 10-2012-0079533

(51) Int. Cl. H01L 45/00

(52) U.S. Cl. CPC H01L 45/1253; H01L 45/1675
USPC 257/4; 438/382

(57) ABSTRACT

A method for fabricating a variable resistance memory device includes forming an insulating layer having a trench extending in a first direction over a substrate, forming first electrode conductive layers on both sidewalls of the trench, forming island-shaped first electrodes by patterning the conductive layers in a second direction crossing the first direction, forming variable resistance patterns over the first electrodes, and forming second electrodes over the variable resistance patterns.

### CROSS-REFERENCE TO RELATED APPLICATIONS

The present application claims priority of Korean Patent Application No. 10-2012-0079533, filed on Jul. 20, 2012, which is incorporated herein by reference in its entirety.

### BACKGROUND

1. Field

Exemplary embodiments of the present invention relate to a semiconductor memory technology, and more particularly, to a variable resistance memory device and a method for fabricating the same.

2. Description of the Related Art

A variable resistance memory device stores data using a variable resistance material that switches between different resistance states depending on a supplied voltage or current. Currently, various variable resistance memory devices such as ReRAM (Resistive Random Access Memory), PCRAM (Phase-change Random Access Memory), FRAM (Ferroelectric Random Access Memory), and MRAM (Magnetic Random Access Memory) have been developed.

FIG. 1 is a cross-sectional view illustrating a conventional variable resistance memory device.

Referring to FIG. 1, the variable resistance memory device includes a bottom electrode 100 over a substrate, a top electrode 120, and a variable resistance material layer 110 interposed therebetween. The variable resistance memory device may be fabricated by a series of processes of forming a bottom electrode 100 over a substrate (not illustrated) having a predetermined lower structure formed therein, depositing a variable resistance material on the resulting structure having the bottom electrode 100 formed thereon, forming a variable resistance material layer 110 by selectively etching the deposited variable resistance material and forming a top electrode 120 over the variable resistance layer 110.

However, during the etch process for forming the variable resistance material layer 110, the sidewalls of the variable resistance material layer 110 may be deformed. In this case, since a leakage current (refer to symbol I) occurs through the sidewalls of the variable resistance material layer 110, implementing a variable resistance memory device having a desired characteristic may become difficult.

Meanwhile, the switching area of the variable resistance material layer 110 may be limited by the bottom electrode 100. In the case of ReRAM of which the resistance is changed by creation and destruction of a conductive filament, the creation and destruction of a conductive filament inside the variable resistance material layer 110 occurs only in an area contacted with the bottom electrode 100.

At this time, when the switching area of the variable resistance material layer 110 is small, the conductive filament is created and destroyed at a constant position. The switching area of the variable resistance material layer 110 may be reduced by decreasing the width W of the bottom electrode 100 to secure the desirable switching characteristic.

However, since the bottom electrode 100 is formed by a mask and etch process, there is a limitation in decreasing the width W of the bottom electrode 100.

### SUMMARY

Exemplary embodiments of the present invention are directed to a variable resistance memory device and a method for fabricating the same, which is capable of securing a uniform switching characteristic, increasing the integration degree, and simplifying the process.

In accordance with an embodiment of the present invention, a method for fabricating a variable resistance memory device includes forming an insulating layer having a trench extending in a first direction over a substrate, forming first electrode conductive layers on both sidewalls of the trench, forming island-shaped first electrodes by patterning the conductive layers in a second direction crossing the first direction, forming variable resistance patterns over the first electrodes, and forming second electrodes over the variable resistance patterns.

In accordance with another embodiment of the present invention, a method for fabricating a variable resistance device includes forming a plurality of first conductive lines over a substrate so that the plurality of first conductive lines are extended in a first direction, forming a first electrode conductive layer over each of the first conductive lines so that the first electrode conductive layer is extended in the first direction and has a smaller width than each of the plurality of the first conductive lines, forming island-shaped first electrodes by patterning the first electrode conductive layer in a second direction crossing the first direction, forming variable resistance patterns over the first electrodes, and forming a plurality of second conductive lines over the variable resistance patterns so that the second conductive lines are extended in the second direction.

In accordance with yet another embodiment of the present invention, a variable resistance memory device includes a plurality of first electrodes of island-shape disposed over a substrate and arranged along first and second directions, a plurality of variable resistance patterns disposed over the plurality of respective first electrodes, respectively, each of the plurality of variable resistance patterns having a larger width than each of the plurality of first electrodes in the first and second directions, and a plurality of second electrodes formed over the plurality of variable resistance patterns.

### BRIEF DESCRIPTION OF THE DRAWINGS

FIG. 1 is a cross-sectional view illustrating a conventional variable resistance memory device.

FIGS. 2A to 2K are diagrams illustrating a variable resistance memory device and a method for fabricating the same in accordance with an embodiment of the present invention.

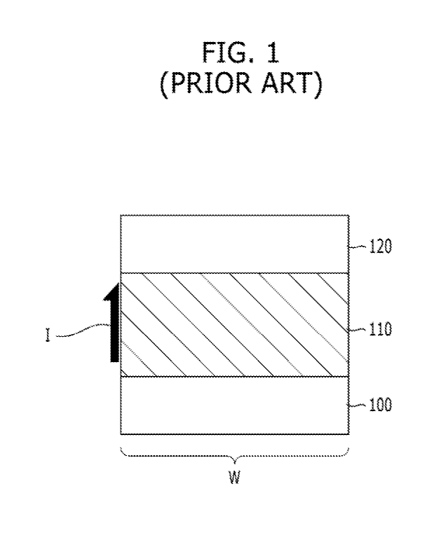

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention. In this specification, ‘connected/coupled’ represents that one component is directly coupled to another component or indirectly coupled through another component. In addition, a singular form may include a plural form as long as it is not specifically mentioned in a sentence.

The drawings are not necessarily to scale and in some instances, proportions may have been exaggerated in order to clearly illustrate features of the embodiments. It should be readily understood that the meaning of “on” and “over” in the present disclosure should be interpreted in the broadest manner such that “on” not only means “directly on” something but also include the meaning of “on” something with an intermediate feature or a layer therebetween, and that “over” not only means the meaning of “over” something may also include the meaning it is “over” something with no intermediate feature or layer therebetween (i.e., directly on something).

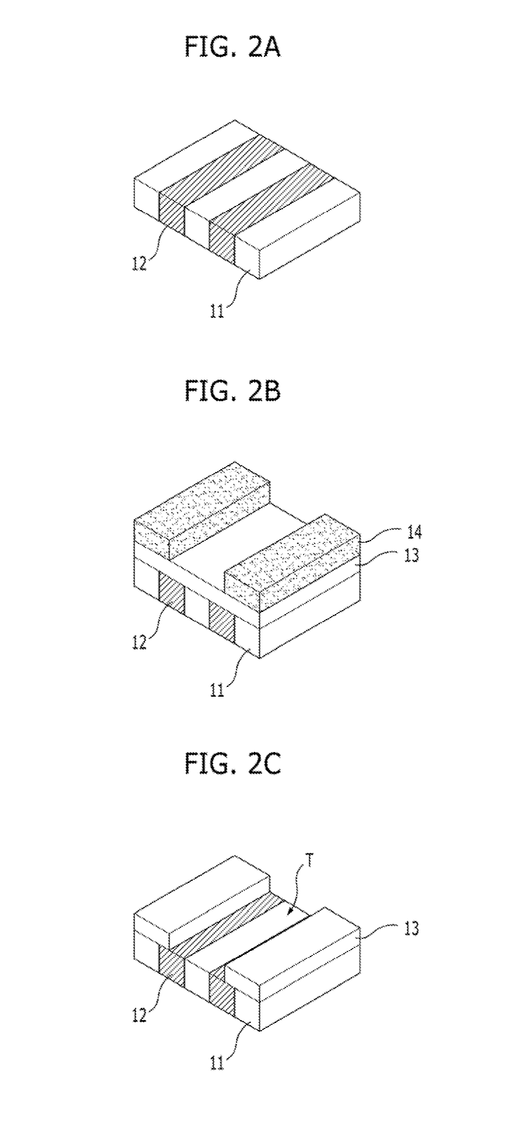

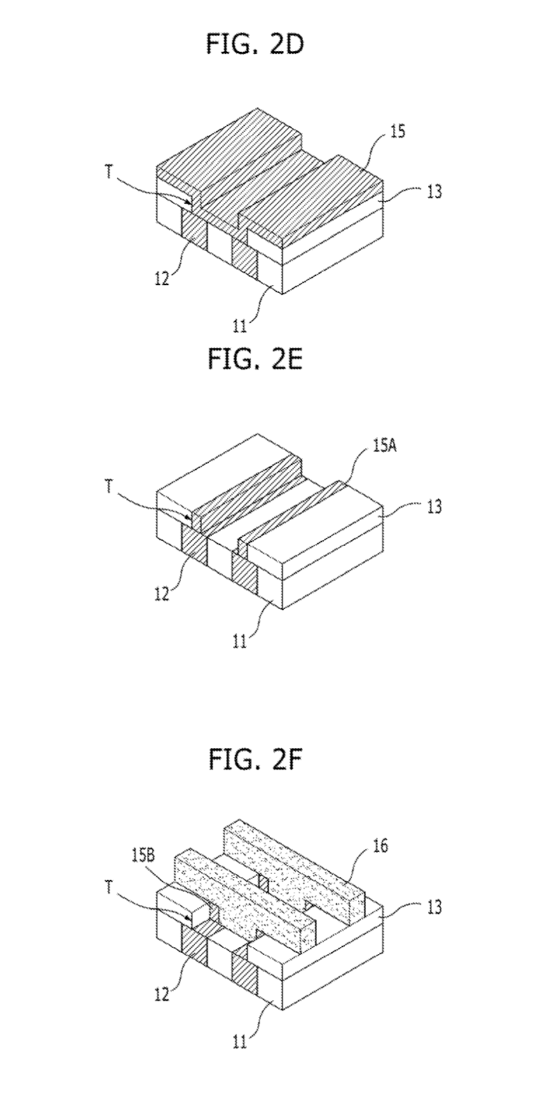

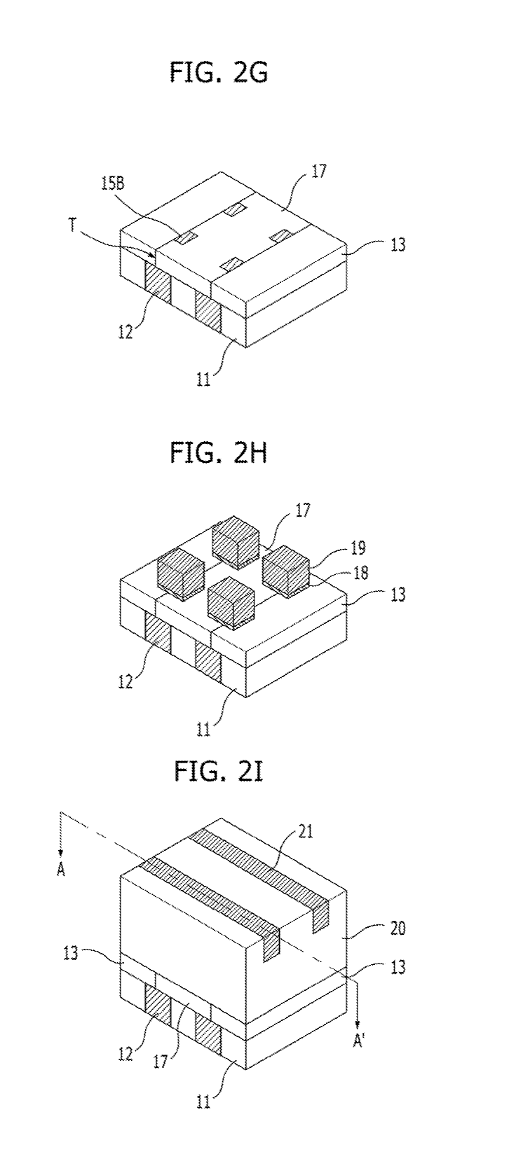

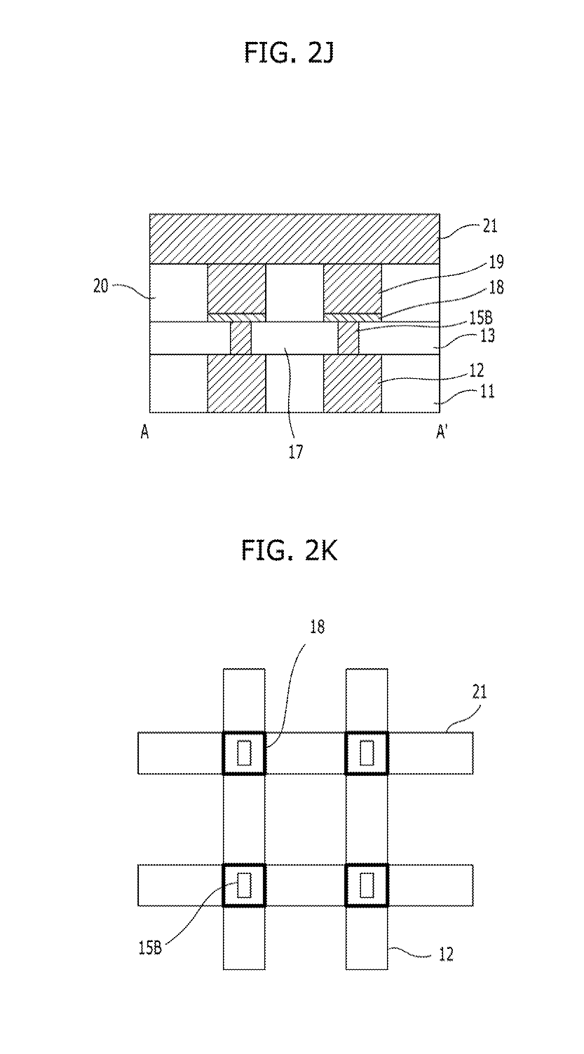

FIGS. 2A to 2K are diagrams illustrating a variable resistance memory device and a method for fabricating the same in accordance with an embodiment of the present invention. FIGS. 2I to 2K are a perspective view, a cross-sectional view, and a plan view of the variable resistance memory device in accordance with the embodiment of the present invention, respectively. FIGS. 2A to 2H are perspective views illustrating intermediate processes for fabricating the device of FIGS. 2I to 2K.

Referring to FIG. 2A, a plurality of lower conductive lines 12 are formed over substrate (not illustrated) having a predetermined structure formed therein to be extended in a first direction. Between the respective lower conductive lines 12, a first insulating layer 11 may be buried.

Specifically, the lower conductive lines 12 may be formed by depositing a conductive material on the substrate and selectively etching the deposited conductive material. Alternatively, the lower conductive lines 12 may be formed by the following process: the first insulating layer 11 is formed over the substrate and selectively etched to form trenches extended in the first direction and a conductive material is buried in the trenches.

The lower conductive line 12 may include a metal such as platinum (Pt), gold (Au), tungsten (W), aluminum (Al) copper (Cu), tantalum (Ta), iridium (Ir), or ruthenium (Ru). Alternatively, the lower conductive line 12 may include a metal nitride such as titanium nitride (TiN), tantalum nitride (TaN), titanium aluminum nitride (TiAlN) or titanium silicon nitride (TiSiN). The first insulating layer 11 may include oxide.

Referring to FIG. 2B, a second insulating layer 13 is formed over the first insulating layer 11 and the lower conductive lines 12. The second insulating layer 13 may include oxide.

Then, a first mask pattern 14 is formed over the second insulating layer 13 to expose an area where a trench is subsequently formed. Here, the first mask pattern 14 has an opening that is extended in the first direction.

Referring to FIG. 2C, the second insulating layer 13 is etched using the first mask pattern 14 as an etch barrier to form a trench T which is extended in the first direction and exposes the lower conductive lines 12. In this embodiment of the present invention, the trench T exposes at least parts of adjacent two lower conductive lines 12 and a space therebetween. Accordingly, both sidewalls of the trench T disposed over the two adjacent lower conductive lines 12, respectively. Then, the first mask pattern 14 is removed.

Referring to FIG. 2D, a conductive layer 15 for forming a bottom electrode is formed over the structure shown in FIG. 2C along the lower profile.

The conductive layer 15 may include a metal or metal nitride, similar to the lower conductive line 12. Furthermore, the conductive layer 15 may be formed by atomic layer deposition (ALD) or chemical vapor deposition (CVD) having a desirable step coverage characteristic. The thickness of the conductive layer 15 may be adjusted to a small thickness by controlling the deposition time.

Referring to FIG. 2E, the conductive layer 15 on the top surface of the second insulating layer 13 and the bottom surface of the trench T is removed by performing a blanket etch process on the conductive layer 15. As a result, the conductive layer 15 is left on both sidewalls of the trench T. Hereafter, the left conductive layer 15 will be referred to as a conductive pattern 15A. Since the conductive pattern 15A is formed along both sidewalls of the trench T, the conductive pattern 15A has a line shape extending in the first direction and overlaps the lower conductive line 12.

Referring to FIG. 2F, a second mask pattern 16 is formed over the structure shown in FIG. 2E to extend in a second direction crossing the first direction, and the conductive pattern 15A is etched using the second mask pattern 16 as an etch barrier. As a result, the conductive pattern 15A is separated into island-shaped patterns. Hereafter, the island-shaped patterns will be referred to as bottom electrodes 15B. The bottom electrodes 15B are arranged over the lower conducive line 12 in the first direction.

Referring to FIG. 2G, the second mask pattern 16 is removed, an insulating material is deposited on the resulting structure, and a planarization process, for example, chemical mechanical polishing (CMP) is performed until the bottom electrodes 15B are exposed. As a result, the rest space of the trench T having the lower electrodes 15B formed therein is filled with the insulating material 17. The insulating material 17 may include oxide.

The plan shape of the bottom electrode 15B formed as a result of this process will be described briefly. The second-direction width of the bottom electrode 15B is decided based on the deposition thickness of the conductive layer 15, and has nothing to do with the mask and etch process. The first-direction width of the bottom electrode 15B may be decided based on the first-direction width of the second mask pattern 16. Therefore, the width of the bottom electrode 15B, that is, the second-direction width of the bottom electrode 15B may be significantly reduced.

Referring to FIG. 2H, a variable resistance material layer and a top-electrode conductive layer are deposited on the structure shown in FIG. 2G and then patterned to form stacked structures of a variable resistance pattern 18 and a top electrode 19.

The stacked structure of the variable resistance pattern 18 and the top electrode 19 may have an island shape connected to each of the bottom electrodes 15B. Furthermore, the stacked structure may have a larger width than the bottom electrode 15B in the first and second directions or the first or second direction. The variable resistance pattern 18 may include a single layer or multilayer including an oxide of metal such as Al, Hf, Zr, La, Nb, Ta, Ni, Ti, Fe, Co, Mn, or W, a perovskite-based material such as SrTiO, BaTiO, or BST, and a solid electrolyte such as GeSe. The variable resistance pattern 18 may include any materials capable of switching between different resistance states depending on an supplied voltage or current. For example, the materials may include any one of materials used for ReRAM (Resistive Random Access Memory), PCRAM (Phase-change Random Access Memory) FRAM (Ferroelectric Random Access Memory), MRAM (Magnetic Random Access Memory) and the like. The top electrode 19 may include a metal or metal nitride, like the lower conductive line 12.

Referring to FIG. 2I, an upper conducive line 21 is formed to extend in the second direction and connected to the top electrodes 19. The rest space of the structure excluding the upper conductive line 21 is filled with a third insulating layer 20.

Specifically, the upper conductive line 21 may be formed by the following process: an insulating material is formed to fill the space between the top electrodes 19 and a conductive material is then deposited and then selectively etched. Alternatively, the upper conductive line 21 may be formed by the following process: the third insulating layer 20 is formed over the structure shown in FIG. 2H and selectively etched to form a trench which is extended in the second direction while exposing the top surfaces of the top electrodes 19, and a conductive material is buried in the trench.

The upper conductive line 21 may include a metal or metal nitride, similar to the lower conductive line 12. The third insulating layer 20 may include oxide.

Through the above-described process, the device illustrated in FIGS. 2I to 2K may be fabricated.

Referring to FIG. 2I as well as FIGS. 2J and 2K, it is possible to implement a cross-point structure including the variable resistance patterns 18 arranged at the respective intersections between the lower conductive lines 12 and the upper conductive lines 21.

Between the lower conductive line 12 and the variable resistance pattern 18, the island-shaped bottom electrode 15B is disposed. The bottom electrode 15B may have a smaller width than the variable resistance pattern 18 in the first and second directions or the first or second direction through etch processes, that is, the blanket etch process of FIG. 2E and the etch process of FIG. 2F using the second mask pattern 16. In this case, the switching area of the variable resistance pattern 18 is limited to an area contacted with the bottom electrode 15B.

Between the upper conductive line 21 and the variable resistance pattern 18, the island-shape top electrode 19 is disposed. In this embodiment of the present invention, since the top electrode 19 and the variable resistance pattern 18 are patterned together, they have substantially the same width.

The variable resistance memory device and the method for fabricating the same in accordance with the embodiment of the present invention may have the following advantages.

First, since the width of the bottom electrode 15B, or particularly, the second-direction width thereof may be significantly reduced, and the switching area of the variable resistance pattern 18 may be reduced, which makes it possible to improve the switching characteristics of the variable resistance memory device.

Furthermore, the width of the variable resistance pattern 18 may be larger than that of the bottom electrode 15B. Therefore, although the sidewalls of the variable resistance pattern 18 are damaged during the etch process, the damaged sidewalls are positioned outside the switching area. Therefore the damage of the sidewalls of the variable resistance pattern 18 may not affect operation characteristics of the variable resistance memory device.

Furthermore, since two bottom electrodes 15B having a small width in the second direction may be formed at the same time, the process may be simplified.

Meanwhile, the above-described embodiment may be modified in various manners.

For example, in the above-described embodiment of the present invention, the variable resistance pattern 18 and the top electrode 19 are etched together, but the present invention is not limited thereto. The variable resistance pattern 18 and the top electrode 19 may be separately etched, and a process for forming a trench and burying an insulating material in the trench may be used to form the variable resistance pattern 18 and the top electrode 19, instead of the etch process.

Alternatively, the formation process of the top electrode 19 may be omitted, and the variable resistance pattern 18 may be directly contacted with the upper conductive line 21. Alternatively, the variable resistance pattern 18 and the upper conductive line 21 may be patterned together in a shape extending in the second direction, similar to the upper conductive line.

In accordance with the embodiments of the present invention, it is possible to secure a uniform switching characteristic, increase the integration degree, and simplify the process.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a variable resistance memory device, comprising:
forming an insulating layer having a trench extending in a first direction over a substrate;
forming first electrode conductive layers on both sidewalls of the trench;
forming island-shaped first electrodes by patterning the conductive layers in a second direction crossing the first direction;
forming variable resistance patterns over the first electrodes; and
forming second electrodes over the variable resistance patterns.

2. The method of claim 1, wherein the forming of the first electrode conductive layers comprises:
forming a conductive material along the entire surface of a structure having the trench formed therein; and
blanket-etching the conductive material.

3. The method of claim 1, further comprising, after the forming of the first electrodes:
forming an insulating material to cover a structure having the first electrodes formed therein; and
performing a planarization process until the first electrode is exposed.

4. The method of claim 1, wherein each of the variable resistance patterns has a larger width than each of the first electrodes in the first and second directions.

5. The method of claim 4, wherein the forming of the variable resistance patterns is performed by a mask and etch process.

6. The method of claim 1, wherein the forming of the variable resistance patterns and the forming of the second electrodes comprise:
sequentially forming a variable resistance material layer and a second electrode conductive layer; and
etching the variable resistance material layer and the second electrode conductive layer using one mask pattern.

7. A method for fabricating a variable resistance device, comprising;
forming a plurality of first conductive lines over a substrate so that the plurality of first conductive lines are extended in a first direction;
forming a first electrode conductive layer over each of the first conductive lines so that the first electrode conductive layer is extended in the first direction and has a smaller width than each of the plurality of the first conductive lines;
forming island-shaped first electrodes by patterning the first-electrode conductive layer in a second direction crossing the first direction;
forming variable resistance patterns over the first electrodes; and
forming a plurality of second conductive lines over the variable resistance patterns so that the second conductive lines are extended in the second direction.

8. The method of claim 7, wherein the forming of the first-electrode conductive layer comprises:
forming an insulating layer over the plurality of first conductive lines, the insulating layer having a trench exposing at least parts of two adjacent first conductive lines and extending in the first direction;
forming a conductive material along the entire surface of a structure having the trench formed therein; and
etching the conductive material through a blanket etch process.

9. The method of claim 7, further comprising, after the forming of the first electrodes:
forming an insulating material to cover a structure having the first electrodes formed therein; and
performing a planarization process until the first electrodes are exposed.

10. The method of claim 7, wherein each of the variable resistance patterns has a larger width than each of the first electrodes in the first and second directions.

11. The method of claim 10, wherein the forming of the variable resistance patterns is performed by a mask and etch process.

12. The method of claim 7, further comprising forming second electrodes between the variable resistance patterns and the plurality of second conductive lines, each of the second electrodes having an island-shape to overlap each of the first electrodes.

13. The method of claim 12, wherein the forming of the variable resistance patterns and the forming of the second electrodes comprise:
sequentially forming a variable resistance material layer and a second electrode conductive layer; and
etching the variable resistance material layer and the second electrode conductive layer using one mask pattern.

14. A variable resistance memory device comprising:
a plurality of first electrodes of island-shape disposed over a substrate and arranged along first and second directions;
a plurality of variable resistance patterns disposed over the plurality of first electrodes, each of the plurality of variable resistance patterns having a larger width than each of the plurality of first electrodes in the first and second directions; and
a plurality of second electrodes formed over the plurality of variable resistance patterns.

15. The variable resistance memory device of claim 14, wherein each of the plurality of first electrodes has a larger first direction width compared to a second direction width.

16. The variable resistance memory device of claim 14, further comprising a plurality of first conductive lines disposed between the substrate and the first electrodes and extended in the first direction, wherein parts of the plurality of first conductive lines are connected to the plurality of first electrodes.

17. The variable resistance memory device of claim 16, wherein each of the plurality of first electrodes has a smaller width than each of the plurality of first conductive lines.

18. The variable resistance memory device of claim 14, wherein each of the plurality of second electrodes has an island shape to overlap each of the plurality of variable resistance patterns.

19. The variable resistance memory device of claim 14, wherein each of the plurality of second electrodes has a line shape which is extended in the second direction and contacted with the plurality of variable resistance patterns.

20. The variable resistance memory device of claim 18, further comprising a plurality of second conductive lines connected to the plurality of second electrodes and extended in the second direction.
